(19) United States
(12) Patent Application Publication
(10) Pub. No.: US 2026/0068228 A1
(43) Pub. Date: Mar. 5, 2026

(54) Thin Film Transistor, Manufacturing Method of Thin Film Transistor and Display Apparatus Comprising the Same

(71) Applicant: LG Display Co., Ltd., Seoul (KR)

(72) Inventors: Jihee Ryu, Paju-si (KR); Jaeman Jang, Paju-si (KR); Younghyun Ko, Paju-si (KR); Sungju Choi, Paju-si (KR)

(21) Appl. No.: 19/269,957

(22) Filed: Jul. 15, 2025

(30) Foreign Application Priority Data
Sep. 3, 2024 (KR) 10-2024-0119005

(51) Int. Cl. H10D 30/67; H10D 30/01

(52) U.S. Cl. CPC H10D 30/6737; H10D 30/031

(57) ABSTRACT

A thin film transistor comprises: an active layer; and a gate electrode overlapping the active layer, wherein the active layer comprises: a channel portion; a first conductive portion disposed on one side of the channel portion; and a second conductive portion disposed on the other side of the channel portion, wherein the first conductive portion comprises: a first hydrogen conducting portion; and a first connection portion disposed between the first hydrogen conducting portion and the channel portion, and wherein the second conductive portion comprises: a second hydrogen conducting portion; and a second connection portion disposed between the second hydrogen conducting portion and the channel portion, wherein a surface resistance of the first hydrogen conducting portion is greater than a surface resistance of the first connection portion, and a surface resistance of the second hydrogen conducting portion is greater than a surface resistance of the second connection portion.

### CROSS-REFERENCE TO RELATED APPLICATION

This application claims the benefit of priority of the Republic of Korea Patent Application No. 10-2024-0119005 filed on Sep. 3, 2024, which is hereby incorporated by reference in its entirety.

### BACKGROUND

### Field of Technology

The present disclosure relates to a thin film transistor, a method for manufacturing a thin film transistor, and a display apparatus (or display device) including a thin film transistor.

### Discussion of the Related Art

Transistors are widely used as switching devices or driving devices in the field of electronic devices (or electronic apparatuses). In particular, thin film transistors are widely used as switching devices in display devices (or display apparatuses) such as liquid crystal display devices (or liquid crystal display apparatuses) or organic light emitting display devices (organic light emitting display apparatuses) because they can be manufactured on glass or plastic substrates.

Thin film transistors can be classified into amorphous silicon thin film transistors in which amorphous silicon is used as an active layer thereof, polycrystalline silicon thin film transistors in which polycrystalline silicon is used as an active layer thereof, and oxide semiconductor thin film transistors in which oxide semiconductor is used as an active layer thereof, based on the material constituting the active layer.

In the case of oxide semiconductor thin film transistors, a conductorization region can be implemented through dry etching.

However, in the process of conductorization through dry etching of an oxide semiconductor layer or in the process of forming a contact hole, the oxide semiconductor layer (in other words, a thin oxide semiconductor layer) is repeatedly exposed. This may cause the oxide semiconductor layer to disappear, resulting in a problem of reduced mobility of the oxide semiconductor thin film transistor.

Recently, research is being continuously conducted to reduce the area repeatedly exposed by the dry etching process and to improve the problem of reduced mobility due to loss of the oxide semiconductor layer.

### SUMMARY

One embodiment of the present disclosure provides a thin film transistor having a reduced area exposed by dry etching.

One embodiment of the present disclosure provides a thin film transistor in which the mobility reduction problem is improved through conductorization using hydrogen.

In accordance with an embodiment of the present disclosure, the above and other objects can be accomplished by the provision of a thin film transistor comprising: an active layer; and a gate electrode overlapping the active layer, wherein the active layer comprises: a channel portion; a first conductive portion disposed on one side of the channel portion; and a second conductive portion disposed on the other side of the channel portion, wherein the first conductive portion comprises: a first hydrogen conducting portion; and a first connection portion disposed between the first hydrogen conducting portion and the channel portion, and wherein the second conductive portion comprises: a second hydrogen conducting portion; and a second connection portion disposed between the second hydrogen conducting portion and the channel portion, wherein a surface resistance of the first hydrogen conducting portion is greater than a surface resistance of the first connection portion, and a surface resistance of the second hydrogen conducting portion is greater than a surface resistance of the second connection portion.

The thin film transistor further includes a gate insulating film disposed on the active layer, the gate insulating film exposes the first connection portion and the second connection portion, and the first connection portion and the second connection portion can each be formed by selective conductorization by means of dry etching.

The thin film transistor further includes a gate insulating film disposed on the active layer, the gate insulating film covers an entire upper surface of the active layer, and the first connecting portion and the second connecting portion can each be formed by selective conductorization by means of doping using a dopant.

The surface resistances of the first hydrogen conducting portion and the second hydrogen conducting portion are each 5×10³ to 15×10³ Ω/□, and the surface resistances of the first connection and the second connection are each 2×10³ to 5×10³ Ω/□.

The thin film transistor further includes a source electrode and a drain electrode which are spaced apart from each other and respectively connected to the active layer, wherein the source electrode can be connected to the first conducting portion through a first contact hole, and the drain electrode can be connected to the second conducting portion through a second contact hole.

The thin film transistor further includes a base substrate, a buffer layer disposed between the base substrate and the active layer, wherein the first contact hole penetrates the first conductive portion and contacts the buffer layer, and a portion of the first contact hole is surrounded by the buffer layer, and the second contact hole penetrates the second conductive portion and contacts the buffer layer, and a portion of the second contact hole is surrounded by the buffer layer.

The thin film transistor further includes a base substrate, a buffer layer disposed between the base substrate and the active layer, wherein the first contact hole is in contact with a groove formed in the first conductive portion, and the first contact hole does not contact the buffer layer, the second contact hole is in contact with a groove formed in the second conductive portion, and the second contact hole may not contact the buffer layer.

The thin film transistor further includes a gate insulating film disposed on the active layer; a hydrogen supply film disposed on the gate insulating film; and a source electrode and a drain electrode spaced apart from each other and respectively connected to the active layer, wherein the hydrogen supply film is disposed between the gate insulating film and the source electrode, and may be disposed between the gate insulating film and the drain electrode.

The hydrogen supply film may include silicon nitride (SiNx).

The hydrogen supply film may not overlap the gate electrode.

The hydrogen supply film does not overlap the first connecting portion and the second connecting portion, and the hydrogen supply film may overlap at least a portion of the first hydrogen conducting portion and may overlap at least a portion of the second hydrogen conducting portion.

The gate electrode, the source electrode, and the drain electrode can be formed using the same material and by the same process.

Another embodiment of the present invention provides a method for manufacturing a thin film transistor, comprising the steps of forming a buffer layer; forming an active layer on the buffer layer; forming a gate insulating film on the active layer; forming a hydrogen supply material layer on the gate insulating film; etching the buffer layer, the gate insulating film, and the hydrogen supply material layer to form a first contact hole, a second contact hole, and a third contact hole; etching the hydrogen supply material layer to form a fourth contact hole and a hydrogen supply film; forming a gate electrode material layer on the hydrogen supply film; etching the gate electrode material layer to form a gate electrode, a source electrode, and a drain electrode; and etching a portion of the gate insulating film to selectively conductorize a portion of the active layer.

The step of etching the gate electrode material layer to form a gate electrode, a source electrode, and a drain electrode may include a step of patterning the gate electrode material layer using a halftone mask.

Another embodiment of the present invention provides a display apparatus (or display device) including the thin film transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1 according to one embodiment of the present disclosure.

FIG. 3 is a cross-sectional view of a thin film transistor according to another embodiment of the present invention.

FIG. 4 is a cross-sectional view of a thin film transistor according to another embodiment of the present disclosure.

FIGS. 5A to 5D are process diagrams showing a manufacturing process of a thin film transistor according to a comparative example.

FIGS. 6A to 6H are process diagrams showing a manufacturing process of a thin film transistor according to one embodiment of the present disclosure.

FIG. 7 is a schematic diagram of a display apparatus (or display device) according to one embodiment of the present disclosure.

FIG. 8 is a circuit diagram for one pixel of FIG. 7 according to one embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the present disclosure. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band (or error range) although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or more elements to another element or more elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when a temporal order is described as “after”, “subsequent”, “next”, and “before”, a case which is not continuous may be included, unless “just” or “direct” is used.

It will be understood that, although the terms “first”, “second”, etc. may be used herein to describe various elements, these elements should not be limited by these terms. These terms are only used to distinguish one element from another element. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

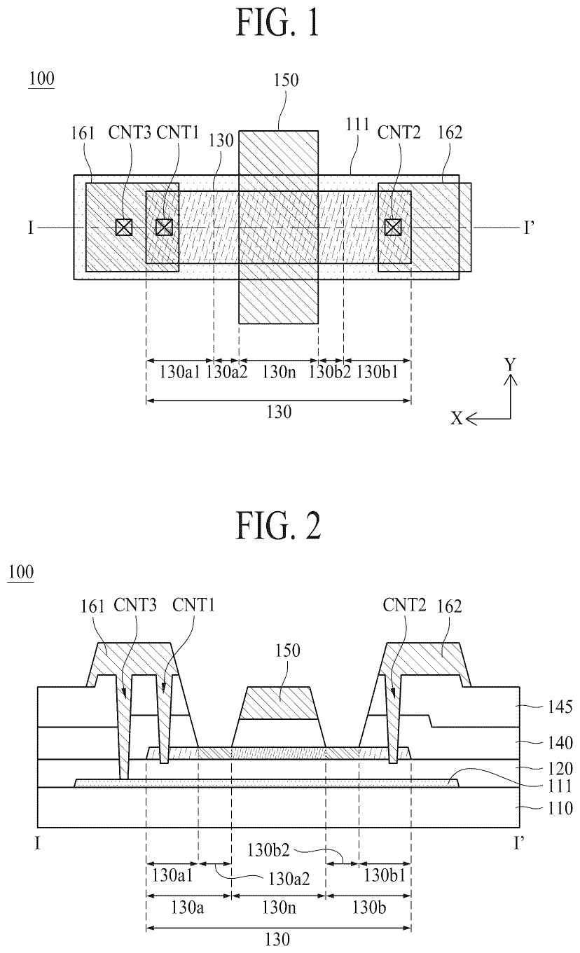

FIG. 1 is a plan view of a thin film transistor (100) according to one embodiment of the present disclosure. FIG. 2 is a cross-sectional view taken along line I-I′ of FIG. 1 according to one embodiment of the present disclosure.

Referring to FIGS. 1 and 2, a thin film transistor (100) according to one embodiment of the present disclosure may include an active layer (130) and a gate electrode (150).

Specifically, referring to FIGS. 1 and 2, a thin film transistor (100) according to one embodiment of the present disclosure includes a base substrate (110), a light-blocking layer (111), a buffer layer (120), an active layer (130), a gate insulating film (140), a hydrogen supply film (145), a gate electrode (150), a source electrode (161), and a drain electrode (162).

Below, components of a thin film transistor (100) according to one embodiment of the present disclosure are described in detail.

The base substrate (110) may be made of glass or plastic. A transparent plastic having flexible properties, such as polyimide, may be used.

When polyimide is used as the material of the base substrate (110), considering that a high-temperature deposition process is performed on the base substrate (110), a heat-resistant polyimide that can withstand high temperatures can be used. In this case, for forming a thin film transistor, processes such as deposition and etching can be performed while the polyimide substrate is disposed on a carrier substrate made of a highly durable material such as glass.

A light blocking layer (111) can be disposed on the base substrate (110).

The light blocking layer (111) may be disposed between the base substrate (110) and the buffer layer (120). The light blocking layer (111) may overlap with the active layer (130). Specifically, the light blocking layer (111) may overlap with a channel portion (130n). The light blocking layer (111) may block light incident from the outside, thereby protecting the channel portion (130n).

The light-blocking layer (111) may be made of a material having light-blocking properties. The light-blocking layer (111) may include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe). According to one embodiment of the present invention, the light-blocking layer (111) may have electrical conductivity.

Referring to FIGS. 1 and 2, the buffer layer (120) may be disposed on the base substrate (110) and the light blocking layer (111).

The buffer layer (120) is formed on the base substrate (110) and may be formed of an inorganic material or an organic material. For example, the buffer layer (120) may include an insulating oxide such as silicon oxide (SiOx) or aluminum oxide (Al₂O₃).

The buffer layer (120) protects the active layer (130) by blocking impurities such as moisture and oxygen flowing in from the base substrate (110) and serves to flatten an upper portion of the base substrate (110), and can be formed as a single layer or multiple layers.

When the buffer layer (120) has multiple layers, each of the multiple layers can be formed of different materials.

Referring to FIGS. 1 and 2, the active layer (130) may be disposed on the buffer layer (120).

The active layer (130) may include a channel portion (130n), a first conductive portion (130a), and a second conductive portion (130b).

Specifically, at least a portion of the channel portion (130n) overlaps with the gate electrode (150) in a plane view, the first conductive portion (130a) is disposed on one side of the channel portion (130n), and the second conductive portion (130b) is disposed on the other side of the channel portion (130n). More specifically, the first conductive portion (130a) and the second conductive portion (130b) do not overlap with the gate electrode (150) in a plane view, respectively.

According to one embodiment of the present invention, the first conductive portion (130a) and the second conductive portion (130b) are spaced apart from each other with the channel portion (130n) therebetween.

According to one embodiment of the present invention, the first conductive portion (130a) includes a first hydrogen conducting portion (130a1) and a first connecting portion (130a2).

Specifically, the first connecting portion (130a2) is disposed between the first hydrogen conducting portion (130a1) and the channel portion (130n). More specifically, the first hydrogen conducting portion (130a1) and the channel portion (130n) are spaced apart from each other with the first connecting portion (130a2) therebetween.

According to one embodiment of the present invention, the second conductive portion (130b) includes a second hydrogen conducting portion (130b1) and a second connecting portion (130b2).

Specifically, the second connecting portion (130b2) is disposed between the second hydrogen conducting portion (130b1) and the channel portion (130n). More specifically, the second hydrogen conducting portion (130b1) and the channel portion (130n) are disposed spaced apart from each other with the second connecting portion (130b2) therebetween.

According to one embodiment of the present disclosure, the surface resistance of the first hydrogen conducting portion (130a1) may be greater than the surface resistance of the first connecting portion (130a2).

According to one embodiment of the present disclosure, the surface resistance of the second hydrogen conducting portion (130b1) may be greater than the surface resistance of the second connecting portion (130b2).

According to one embodiment of the present invention, the active layer (130) may be formed of a semiconductor material. The active layer (130) may include an oxide semiconductor material.

The oxide semiconductor material may include, for example, at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, one embodiment of the present invention is not limited thereto, and the active layer (130) may be made of other oxide semiconductor materials known in the art.

The first connecting portion (130a2) and the second connecting portion (130b2) can be formed by selective conductorization for the active layer (130) made of a semiconductor material. According to one embodiment of the present disclosure, selective conductorization means imparting conductivity to a specific portion of the active layer (130) so that it can function as a conductor. A portion that is imparted conductivity by selective conductorization is conductorized, and a portion that is not imparted conductivity is not conductorized.

According to one embodiment of the present invention, selective conductorization can be achieved by doping using a dopant or dry etching.

For example, selective conductorization for the active layer (130) may be achieved by dopant doping using a gate electrode (150), a metal layer, or a photoresist pattern as a mask. According to one embodiment of the present invention, implanting a dopant or dopant ion into a selected region of the active layer (130) is referred to as dopant doping. The dopant may include, for example, at least one of boron (B), phosphorus (P), fluorine (F), and hydrogen (H).

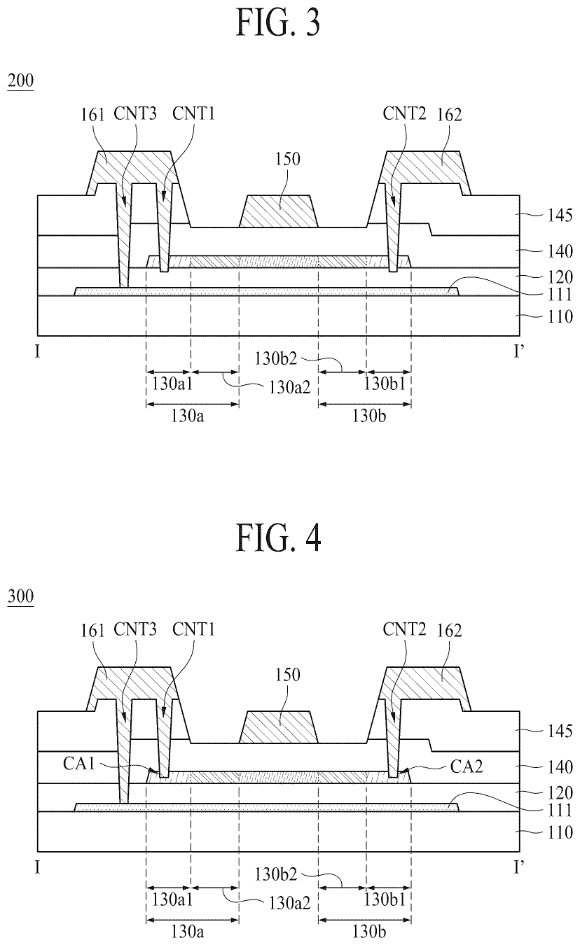

In the case where selective conductorization is achieved for the active layer (130) by doping using a dopant, a region of the active layer (130) doped with a dopant is selectively conductorized and becomes a first connection portion (130a2) or a second connection portion (130b2). A region of the active layer (130) not doped with a dopant is not conductorized and can become a channel portion (130n) (see FIG. 3).

In addition, selective conductorization for the active layer (130) may be achieved by dry etching applied in a process of patterning the gate insulating film (140). For example, in the process of dry etching the gate insulating film (140), a portion of the active layer (130) exposed by the dry etching may be selectively conductorized and may become a first connection portion (130a2) or a second connection portion (130b2). A portion of the active layer (130) protected by the gate insulating film (140) may not be conductorized and may become a channel portion (130n) (see FIG. 2).

However, one embodiment of the present disclosure is not limited thereto, and the active layer (130) may be selectively conductorized by other methods known in the art.

The first connecting portion (130a2) and the second connecting portion (130b2) do not overlap with the gate electrode (150). The first connecting portion (130a2) and the second connecting portion (130b2) have superior electrical conductivity and high mobility compared to the channel portion (130n). Therefore, the first connecting portion (130a2) and the second connecting portion (130b2) can each function as wiring.

According to one embodiment of the present disclosure, a portion of the first hydrogen conducting portion (130a1) and a portion of the second hydrogen conducting portion (130b1) are formed by conductorization using hydrogen (H).

For example, the first hydrogen conducting portion (130a1) is formed by conductorization using hydrogen (H), and the second hydrogen conducting portion (130b1) is formed by conductorization using hydrogen (H).

In order to form a first hydrogen conducting portion (130a1) and a second hydrogen conducting portion (130b1) by conductorization using hydrogen, a hydrogen supply film (145) including silicon nitride (SiNx:H) containing hydrogen can be formed on the active layer (130).

Specifically, when a hydrogen supply film (145) including silicon nitride (SiNx:H) containing hydrogen is formed on the first hydrogen conducting portion (130a1) and the second hydrogen conducting portion (130b1), the conductivity can be increased by conductorizing the first hydrogen conducting portion (130a1) and the second hydrogen conducting portion (130b1) using hydrogen supplied to the first hydrogen conducting portion (130a1) and the second hydrogen conducting portion (130b1).

According to one embodiment of the present disclosure, the surface resistivity of the first hydrogen conducting portion (130a1) and the second hydrogen conducting portion (130b1) are respectively 5×10³ to 15×10³ Ω/□ (that is, ohm/square or Ω/m²). According to one embodiment of the present invention, the surface resistances of the first connection portion (130a2) and the second connection portion (130b2) are each 2×10³ to 5×10³ Ω/□.

According to one embodiment of the present disclosure, the active layer (130) may have a multilayer structure. For example, although not shown in the drawing, the active layer (130) may include a first active layer and a second active layer.

The first active layer and the second active layer may include the same semiconductor material or may include different semiconductor materials.

According to one embodiment of the present disclosure, the thin film transistor (for example, the thin film transistor 100 as shown in FIG. 2 or the thin film transistor 200 as shown in FIG. 3) may further include a gate insulating film (140) between the active layer (130) and the gate electrode (150). Specifically, the gate insulating film (140) may cover the entire upper surface of the active layer (130). FIG. 3 illustrates a configuration in which the gate insulating film (140) covers the entire upper surface of the active layer (130).

However, one embodiment of the present disclosure is not limited thereto, and the gate insulating film (140) may expose a part of the active layer (130). FIG. 2 illustrates a view in which the gate insulating film (140) exposes a part of the active layer (130). Specifically, FIG. 2 illustrates a view in which the gate insulating film (140) exposes a first connection portion (130a2) and a second connection portion (130b2) of the active layer (130).

The gate insulating film (140) may include at least one of silicon oxide, silicon nitride, and metal oxide. The gate insulating film (140) may have a single film structure or a multilayer film structure. The gate insulating film (140) protects the channel portion (130n).

Referring to FIGS. 1 and 2, the gate electrode (150) is disposed on the gate insulating film (140). The gate electrode (150) overlaps the channel portion (130n) of the active layer (130).

The gate electrode (150) is made of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), or titanium (Ti). The gate electrode (150) may have a multilayer film structure including at least two conductive films having different physical properties.

According to one embodiment of the present disclosure, the thin film transistor (100) further includes a hydrogen supply film (145) on the gate insulating film (140).

According to one embodiment of the present disclosure, the hydrogen supply film (145) includes a silicon nitride film (SiNx). Specifically, the hydrogen supply film (145) may include silicon nitride (SiNx:H) containing hydrogen.

The hydrogen supply film (145) includes silicon nitride (SiNx:H) containing hydrogen, thereby supplying hydrogen (H) to the first hydrogen conducting portion (130a1) and the second hydrogen conducting portion (130b1) of the active layer (130), thereby making the first hydrogen conducting portion (130a1) and the second hydrogen conducting portion (130b1) conductive. As a result, the conductivity of the first hydrogen conducting portion (130a1) and the second hydrogen conducting portion (130b1) can be increased.

According to one embodiment of the present disclosure, the hydrogen supply film (145) does not overlap the gate electrode (150) in a plane view. Specifically, the hydrogen supply film (145) may not overlap the channel portion (130n), the first connection portion (130a2), and the second connection portion (130b2). More specifically, the hydrogen supply film (145) may overlap a portion of the first hydrogen conducting portion (130a1) and a portion of the second hydrogen conducting portion (130b1). For example, the hydrogen supply film (145) may be disposed between the gate insulating film (140) and the source electrode (161) and may be disposed between the gate insulating film (140) and the drain electrode (162).

As a result, hydrogen conductorization by means of the hydrogen supply film (145) may proceed in the first hydrogen conducting portion (130a1) and the second hydrogen conducting portion (130b1) of the active layer (130), and hydrogen conductorization by means of the hydrogen supply film (145) may not proceed in the channel portion (130n), the first connecting portion (130a2), and the second connecting portion (130b2).

Referring to FIGS. 1 and 2, a source electrode (161) and a drain electrode (162) are disposed on a hydrogen supply film (145).

The source electrode (161) and the drain electrode (162) have the same material as the gate electrode (150) and can be manufactured by the same process.

The source electrode (161) and the drain electrode (162) may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The source electrode (161) and the drain electrode (162) may each have a multilayer film structure including at least two conductive films having different physical properties.

Referring to FIGS. 1 and 2, the source electrode (161) and the drain electrode (162) are connected to the first conductive portion (130a) and the second conductive portion (130b) through a first contact hole (CNT1) and a second contact hole (CNT2), respectively. Specifically, the source electrode (161) and the drain electrode (162) are in contact with the first hydrogen conducting portion (130a1) and the second hydrogen conducting portion (130b1) respectively, and are connected to the active layer (130).

When the buffer layer (120), the gate insulating film (140), and the hydrogen supply film (145) are etched so that a third contact hole (CNT3) can be connected to the light-blocking layer (111), the first contact hole (CNT1) and the second contact hole (CNT2) can penetrate the active layer (130).

According to one embodiment of the present disclosure, the first contact hole (CNT1) can penetrate a part of the first conductive portion (130a) and come into contact with the buffer layer (120).

Specifically, when forming the first contact hole (CNT1), a portion of the buffer layer (120) may be etched. For example, a portion of the first contact hole (CNT1) may be surrounded by the buffer layer (120).

According to one embodiment of the present disclosure, the second contact hole (CNT2) penetrates a part of the second conductive portion (130b) and comes into contact with the buffer layer (120).

Specifically, when forming the second contact hole (CNT2), a part of the buffer layer (120) may be etched. For example, a part of the second contact hole (CNT2) may be surrounded by the buffer layer (120).

Referring to FIGS. 1 and 2, the source electrode (161) can be connected to the light blocking layer (111) through the third contact hole (CNT3).

The first contact hole (CNT1), the second contact hole (CNT2), and the third contact hole (CNT3) can be formed by the same process. In addition, the first contact hole (CNT1), the second contact hole (CNT2), and the third contact hole (CNT3) can penetrate the gate insulating film (140) and the hydrogen supply film (145) to contact the active layer (130) and the light blocking layer (111), respectively.

FIG. 3 is a cross-sectional view of a thin film transistor (200) according to another embodiment of the present disclosure.

The thin film transistor (200) illustrated in FIG. 3 has a gate insulating film (140) that covers the entire upper surface of the active layer (130) compared to the thin film transistor (100) illustrated in FIGS. 1 and 2.

At this time, selective conductorization is achieved in the active layer (130) by dopant doping. The region of the active layer (130) that is doped with a dopant is selectively conductorized and becomes a first connection portion (130a2) or a second connection portion (130b2). The region of the active layer (130) that is not doped with a dopant is not conductorized and can become a channel portion (130n).

FIG. 4 is a cross-sectional view of a thin film transistor (300) according to another embodiment of the present disclosure.

According to one embodiment of the present disclosure, the first contact hole (CNT1) is in contact with a first groove (CA1) formed in the first conductive portion (130a1), and the first contact hole (CNT1) may not be in contact with the buffer layer (120).

According to one embodiment of the present disclosure, the second contact hole (CNT2) may be in contact with a second groove (CA2) formed in the second conductive portion (130b1), and the second contact hole (CNT2) may not be in contact with the buffer layer (120).

For example, FIG. 4 illustrates that the first contact hole (CNT1) and the second contact hole (CNT2) do not completely penetrate the first conductive portion (130a1) and the second conductive portion (130b1), respectively.

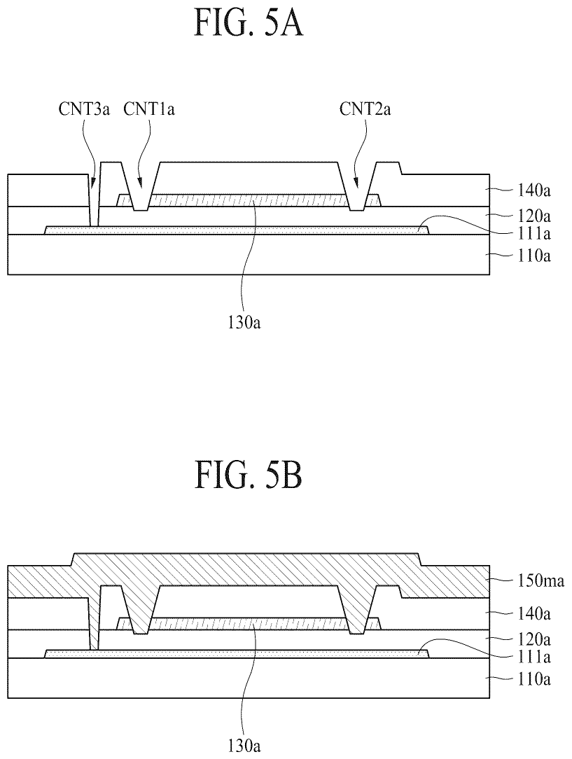

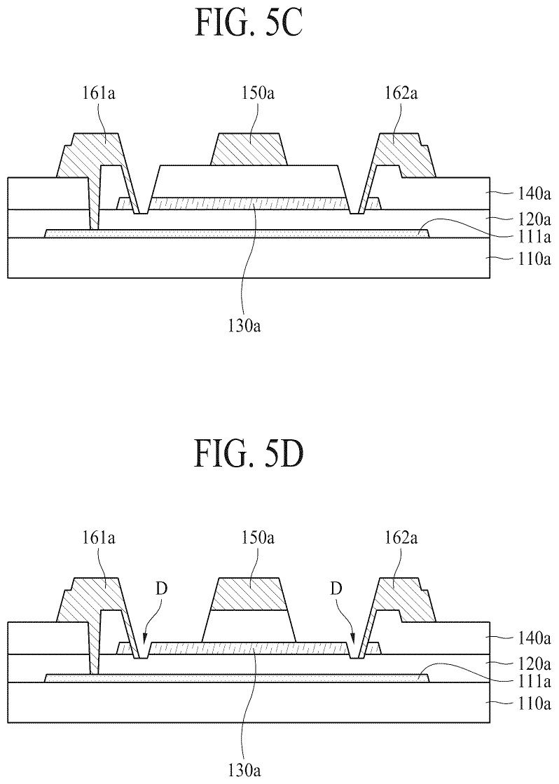

FIGS. 5A to 5D are process diagrams showing a manufacturing process of a thin film transistor according to a comparative example.

The thin film transistor of FIGS. 5A to 5D includes a base substrate (110a), a buffer layer (120a), an active layer (130a), a gate insulating film (140a), a gate electrode (150a), a source electrode (161a), and a drain electrode (162a).

The base substrate (110a), the buffer layer (120a), the active layer (130a), the gate insulating film (140a), the gate electrode (150a), the source electrode (161a), and the drain electrode (162a) of the thin film transistor according to the comparative example may be made of the same material as the base substrate (110), the buffer layer (120), the active layer (130), the gate insulating film (140), the gate electrode (150), the source electrode (161), and the drain electrode (162) of the thin film transistor (100, 200) according to one embodiment of the present invention.

Referring to FIG. 5A, a light-blocking layer (111a), a buffer layer (120a), an active layer (130a), and a gate insulating film (140a) are sequentially formed on a base substrate (110a), and the gate insulating film (140a), the active layer (130a), and the buffer layer (120a) are etched to form contact holes (for example, a first contact hole CNTla, a second contact hole CNT2a, and a third contact hole CNT3a).

Referring to FIG. 5B, a gate electrode material layer (150ma) is formed on the gate insulating film (140a).

Referring to FIG. 5C, the gate electrode material layer (150ma) is patterned to form a gate electrode (150a), a source electrode (161a), and a drain electrode (162a).

Referring to FIG. 5D, the gate insulating film (140a) can be etched through dry etching to selectively conductorize the active layer (130a).

Referring to the thin film transistor according to the comparative example illustrated in FIG. 5D, the gate insulating film (140a) and the active layer (130a) can be etched through dry etching so that the source electrode (161a) and the drain electrode (162a) can come into contact with the active layer (130a).

Additionally, in order to conductorize the active layer (130a), the gate insulating film (140a) can be etched through dry etching.

At this time, the source electrode (161a) and the drain electrode (162a) come into contact with the active layer (130a), and a dry etching process is repeatedly performed to make the active layer (130a) conductive.

Specifically, in the region (D) where the source electrode (161a) and the drain electrode (162a) come into contact with the active layer (130a), the active layer (130a) may be over-etched, resulting in a problem where almost no active layer (130a) remains in the region.

Due to this, the loss of the active layer (130a) may cause the resistance in the active layer (130a) to increase and the mobility to decrease.

Unlike the comparative example, the thin film transistor (100, 200) according to one embodiment of the present invention can improve the problem of reduced mobility of the active layer (130) by reducing the area of the active layer (130) exposed by dry etching.

In addition, by supplying hydrogen to the first hydrogen conducting portion (130a1) and the second hydrogen conducting portion (130b1) of the active layer (130) by means of the hydrogen supply film (145), the problem of reduced mobility can be improved by making the first hydrogen conducting portion (130a1) and the second hydrogen conducting portion (130b1) conductive.

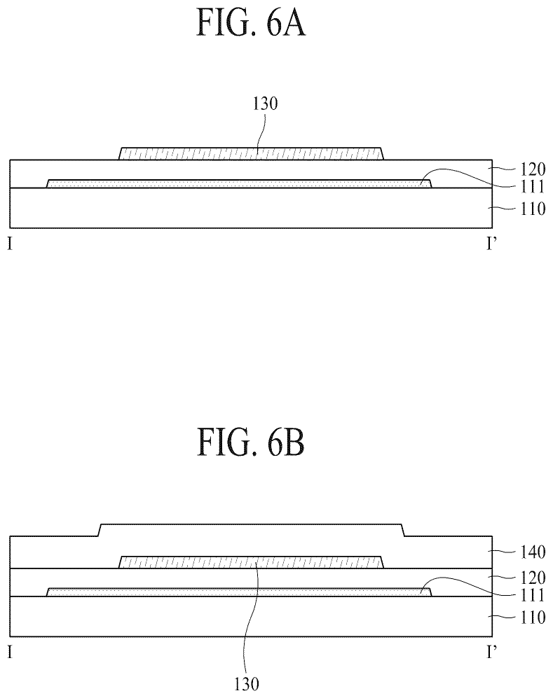

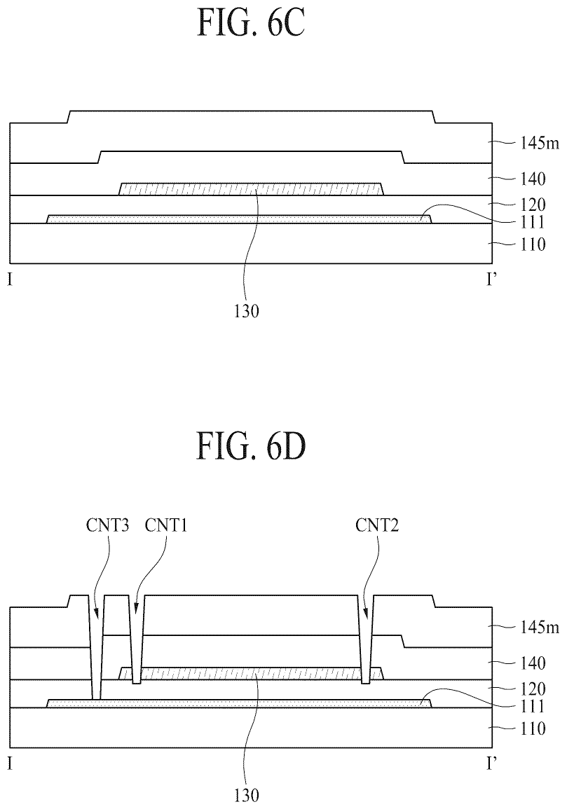

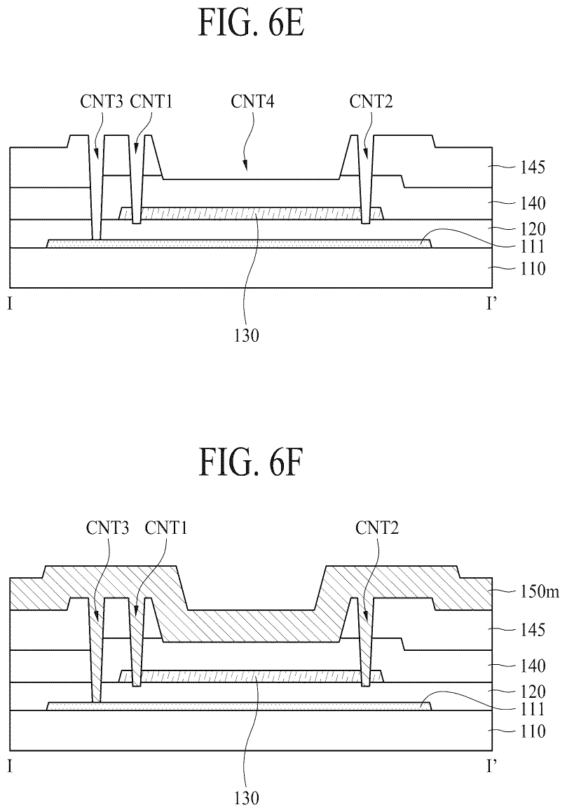

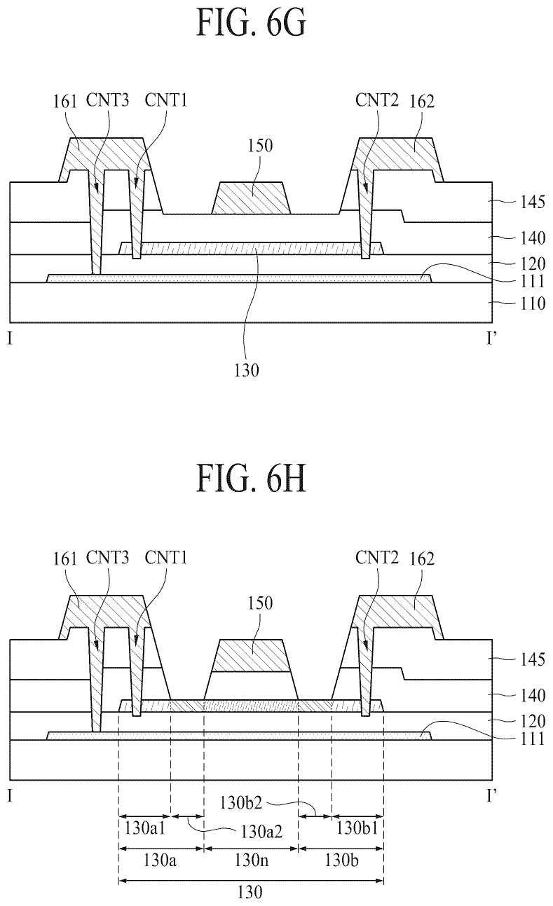

FIGS. 6A to 6H are process diagrams showing a manufacturing process of a thin film transistor according to one embodiment of the present disclosure.

The cross-sectional views of the thin film transistors illustrated in FIGS. 6A to 6H correspond to the cross-sectional views of the thin film transistor (100) illustrated in FIG. 2.

A method for manufacturing a thin film transistor according to one embodiment of the present invention comprises the steps of forming a buffer layer (120), forming an active layer (130) on the buffer layer (120), forming a gate insulating film (140) on the active layer (130), forming a hydrogen supply material layer (145m) on the gate insulating film (140), etching the buffer layer (120), the gate insulating film (140), and the hydrogen supply material layer (145m) to form a first contact hole (CNT1), a second contact hole (CNT2), and a third contact hole (CNT3), etching the hydrogen supply material layer (145m) to form a fourth contact hole (CNT4) and a hydrogen supply film (145), forming a gate electrode material layer (150m) on the hydrogen supply film (145), etching the gate electrode material layer (150m) to form a gate electrode (150), a source electrode (161), and a drain electrode and etching a part of a gate insulating film (140) to selectively conductorize a part of the active layer (130).

Referring to FIG. 6A, a light blocking layer (111), a buffer layer (120), and an active layer (130) are formed in sequence on a base substrate (110).

Referring to FIG. 6B, a gate insulating film (140) is formed on the buffer layer (120) and the active layer (130). The gate insulating film (140) can cover the entire upper surface of the active layer (130).

Referring to FIG. 6C, a hydrogen supply material layer (145m) is formed on a gate insulating film (140). The hydrogen supply material layer (145m) can cover the entire upper surface of the gate insulating film (140).

According to one embodiment of the present invention, the hydrogen supply material layer (145m) may include silicon nitride (SiNx). Specifically, the hydrogen supply material layer (145m) may include silicon nitride (SiNx:H) containing hydrogen.

Referring to FIG. 6D, the buffer layer (120), the gate insulating film (140), and the hydrogen supply material layer (145m) can be etched to form a first contact hole (CNT1), a second contact hole (CNT2), and a third contact hole (CNT3).

The first contact hole (CNT1), the second contact hole (CNT2), and the third contact hole (CNT3) are connected to the active layer (130) and the light-blocking layer (111), respectively. In addition, when the buffer layer (120), the gate insulating film (140), and the hydrogen supply material layer (145m) are etched so that the third contact hole (CNT3) is connected to the light-blocking layer (111), the first contact hole (CNT1) and the second contact hole (CNT2) can penetrate the active layer (130).

Referring to FIG. 6E, the hydrogen supply material layer (145m) can be etched to form a fourth contact hole (CNT4) and a hydrogen supply film (145).

FIG. 6E illustrates a portion of the gate insulating film (140) being etched while etching the hydrogen supply material layer (145m), but the present disclosure is not limited thereto, and the gate insulating film (140) may not be etched.

Referring to FIG. 6F, a gate electrode material layer (150m) can be formed on the hydrogen supply film (145).

The gate electrode material layer (150m) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti).

The gate electrode material layer (150m) can cover the entire upper surface of the hydrogen supply film (145) and the entire upper surface of the exposed gate insulating film (140).

Referring to FIG. 6G, a gate electrode material layer (150m) can be etched to form a gate electrode (150), a source electrode (161), and a drain electrode (162).

At this time, the step of etching the gate electrode material layer (150m) to form the gate electrode (150), the source electrode (161), and the drain electrode (162) may include a step of patterning the gate electrode material layer (150m) using a halftone mask (not shown).

Referring to FIG. 6H, a portion of the gate insulating film (140) may be etched to selectively conductorize a portion of the active layer (130).

A first connection portion (130a2) and a second connection portion (130b2) of the active layer (130) can each be formed by selective conductorization for the active layer (130).

Although FIG. 6H illustrates a part of the gate insulating film (140) being etched to selectively conductorize a part of the active layer (130), the present disclosure is not limited thereto. Selective conductorization for the active layer (130) may also be achieved by dopant doping.

In addition, a first hydrogen conducting portion (130a1) and a second hydrogen conducting portion (130b1) of the active layer (130) can be conductorized by hydrogen supplied from a hydrogen supply film (145) including silicon nitride (SiNx:H) containing hydrogen.

According to one embodiment of the present disclosure, the surface resistances of the first hydrogen conducting portion (130a1) and the second hydrogen conducting portion (130b1) are respectively 5×10³ to 15×10³ Ω/□. The surface resistances of the first connection portion (130a2) and the second connection portion (130b2) are each 2×10³ to 5×10³ Ω/□.

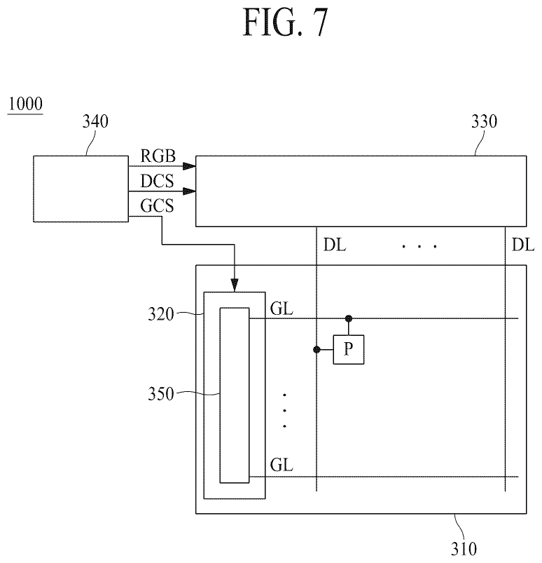

FIG. 7 is a schematic diagram illustrating a display apparatus 1000 according to further still another embodiment of the present disclosure.

As shown in FIG. 7, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistor 100. According to one embodiment of the present disclosure, the gate driver 320 may include the above-described thin film transistors 100. The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistor 100.

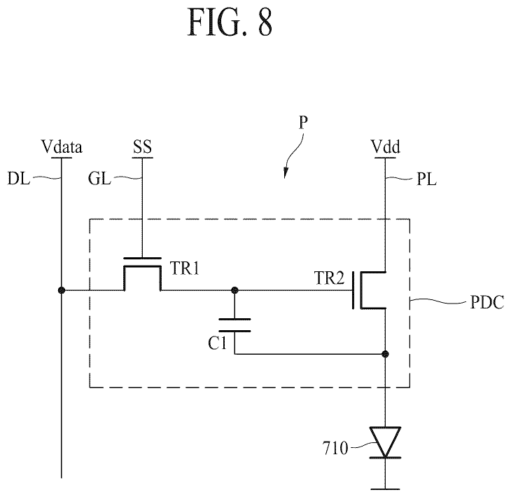

FIG. 8 is a circuit view illustrating any one pixel P of FIG. 7 according to one embodiment of the present disclosure.

The circuit view of FIG. 8 is an equivalent circuit view for the pixel P of the display apparatus 1000 that includes an organic light emitting diode (OLED) as a display element 710.

Referring to FIG. 8, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 8 includes a first thin film transistor TR1 that is a switching transistor and a second thin film transistor TR2 that is a driving transistor. The display apparatus 1000 according to another embodiment of the present disclosure may include at least one the above-described thin film transistor 100.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

A driving power line PL provides a driving voltage Vdd to the display element 710 and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

The pixel drive circuit (PDC) according to another embodiment of the present invention may be formed in a variety of structures other than those described above. The pixel drive circuit (PDC) may include, for example, three or more thin film transistors.

According to the present disclosure, the following advantageous effects may be obtained.

A thin film transistor according to one embodiment of the present disclosure can prevent loss of an active layer by reducing an area exposed by dry etching.

A thin film transistor according to one embodiment of the present disclosure can improve the problem of reduced mobility through conductorization using hydrogen.

In addition to the effects mentioned above, other features and advantages of the present disclosure are described below or may be clearly understood by those skilled in the art to which the present invention pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer; and
a gate electrode overlapping the active layer,
wherein the active layer includes:
a channel portion;
a first conductive portion on one side of the channel portion; and
a second conductive portion on another side of the channel portion,
wherein the first conductive portion includes:
a first hydrogen conducting portion; and
a first connection portion between the first hydrogen conducting portion and the channel portion,
wherein the second conductive portion includes:
a second hydrogen conducting portion; and
a second connection portion between the second hydrogen conducting portion and the channel portion,
wherein a surface resistance of the first hydrogen conducting portion is greater than a surface resistance of the first connection portion, and
wherein a surface resistance of the second hydrogen conducting portion is greater than a surface resistance of the second connection portion.

2. The thin film transistor of claim 1, further comprising:
a gate insulating film on the active layer,
wherein the gate insulating film exposes the first connection portion and the second connection portion.

3. The thin film transistor of claim 1, further comprising:
a gate insulating film on the active layer,
wherein the gate insulating film covers an entire upper surface of the active layer.

4. The thin film transistor of claim 1, wherein the surface resistance of the first hydrogen conducting portion and the surface resistance of the second hydrogen conducting portion are each 5×10³ to 15×10³ Ω/□, respectively, and
wherein the surface resistance of the first connection portion and the surface resistance of the second connection portion are each 2×10³ to 5×10³ Ω/□, respectively.

5. The thin film transistor of claim 1, further comprising:
a source electrode and a drain electrode that are spaced apart from each other and respectively connected to the active layer,
wherein the source electrode is connected to the first hydrogen conducting portion through a first contact hole and the drain electrode is connected to the second hydrogen conducting portion through a second contact hole.

6. The thin film transistor of claim 5, further comprising:
a base substrate; and
a buffer layer between the base substrate and the active layer,
wherein the first contact hole penetrates the first conductive portion and contacts the buffer layer, and a portion of the first contact hole is surrounded by the buffer layer, and
wherein the second contact hole penetrates the second conductive portion and contacts the buffer layer, and a portion of the second contact hole is surrounded by the buffer layer.

7. The thin film transistor of claim 5, further comprises:
a base substrate; and
a buffer layer between the base substrate and the active layer,
wherein the first contact hole is in contact with a groove formed in the first conductive portion and the first contact hole does not contact the buffer layer,
wherein the second contact hole is in contact with a groove formed in the second conductive portion and the second contact hole does not contact the buffer layer.

8. The thin film transistor of claim 1, further comprises:
a gate insulating film on the active layer;
a hydrogen supply film on the gate insulating film; and
a source electrode and a drain electrode spaced apart from each other and respectively connected to the active layer,
wherein the hydrogen supply film is between the gate insulating film and the source electrode, and is disposed between the gate insulating film and the drain electrode.

9. The thin film transistor of claim 8, wherein the hydrogen supply film includes silicon nitride.

10. The thin film transistor of claim 8, wherein the hydrogen supply film is non-overlapping with the gate electrode.

11. The thin film transistor of claim 8, wherein the hydrogen supply film is non-overlapping with the first connection portion and the second connection portion, and wherein the hydrogen supply film overlaps at least a portion of the first hydrogen conducting portion and overlaps at least a portion of the second hydrogen conducting portion.

12. The thin film transistor of claim 5, wherein the gate electrode, the source electrode, and the drain electrode include a same material.

13. A manufacturing method of a thin film transistor, the manufacturing method comprising:
forming a buffer layer;
forming an active layer on the buffer layer;
forming a gate insulating film on the active layer;
forming a hydrogen supply material layer on the gate insulating film;
etching the buffer layer, the gate insulating film, and the hydrogen supply material layer to form a first contact hole, a second contact hole, and a third contact hole;
etching the hydrogen supply material layer to form a fourth contact hole and a hydrogen supply film;
forming a gate electrode material layer on the hydrogen supply film;
etching the gate electrode material layer to form a gate electrode, a source electrode, and a drain electrode; and
etching a portion of the gate insulating film to selectively conductorize a portion of the active layer.

14. The manufacturing method of a thin film transistor of claim 13, wherein the active layer is formed to include:
a channel portion;
a first conductive portion on one side of the channel portion; and
a second conductive portion disposed on another side of the channel portion,
wherein the first conductive portion includes:
a first hydrogen conducting portion; and
a first connection portion between the first hydrogen conducting portion and the channel portion,
wherein the second conductive portion includes:
a second hydrogen conducting portion; and
a second connection portion between the second hydrogen conducting portion and the channel portion,
wherein a surface resistance of the first hydrogen conducting portion is greater than a surface resistance of the first connection portion, and
wherein a surface resistance of the second hydrogen conducting portion is greater than a surface resistance of the second connection portion.

15. The manufacturing method of a thin film transistor of claim 14, wherein the surface resistance of the first hydrogen conducting portion and the surface resistance of the second hydrogen conducting portion are each set to be 5×10³ to 15×10³ Ω/□, respectively, and wherein the surface resistance of the first connection portion and the surface resistance of the second connection portion are each set to be 2×10³ to 5×10³ Ω/□, respectively.

16. The manufacturing method of a thin film transistor of claim 13, wherein the step of etching the gate electrode material layer to form the gate electrode, the source electrode, and the drain electrode includes a step of patterning the gate electrode material layer using a halftone mask.

17. A display apparatus comprising the thin film transistor of claim 1.
